(19) United States
(12) Patent Application Publication
(10) Pub. No.: US 2009/0321924 A1
(43) Pub. Date: Dec. 31, 2009

(54) Power Semiconductor Module

(75) Inventors: Sunao Funakoshi, Kasumigaura-shi (JP); Katsumi Ishikawa, Hitachinaka-shi (JP)

Correspondence Address: CROWELL & MORING LLP;INTELLECTUAL PROPERTY GROUP, P.O. BOX 14300, WASHINGTON, DC, 20044-4300, US

(73) Assignee: Hitachi, Ltd., Tokyo (JP)

(21) Appl. No.: 12/493,629

(22) Filed: Jun. 29, 2009

(30) Foreign Application Priority Data
Jun. 30, 2008 (JP) 2008-169779

(51) Int. Cl. H01L 23/34

(52) U.S. Cl. 257/722; 257/E23.08

(57) ABSTRACT

A power semiconductor module includes: a power semiconductor device; a first heat dissipation plate; a second heat dissipation plate; a first channel; a second channel; a first channel wall; a second channel wall; a first refrigerant outlet provided on the first channel wall in a position corresponding to the power semiconductor device; a second refrigerant outlet provided on the second channel wall in a position corresponding to the power semiconductor device; first pin fins provided on at least one of the first heat dissipation plate and the second heat dissipation plate so as to be arranged radially around at least one of the first refrigerant outlet and the second refrigerant outlet; and second pin fins arranged in a staggered manner or in a tessellated manner around the first pin fins that are arranged radially.

The disclosure of the following priority application is herein incorporated by reference:

Japanese Patent Application No. 2008-169779 filed Jun. 30, 2008

### BACKGROUND OF THE INVENTION

1. Field of the Invention

The present invention relates to a power semiconductor module.

2. Description of Related Art

In recent years, power increase in an inverter that is used for a hybrid vehicle or the like has been increasingly demanded, requiring a power module that constitutes the inverter to output higher power. On the other hand, since a vehicle has a limitation on space to place its components, a power module is required to be as small in size as possible. It is essential to improve cooling performance of a power module so as to allow high power and small size to be compatible. Conventional technologies for increasing cooling performance include the structure in which, as disclosed in Japanese Laid Open Patent Publication No. 2007-251076 (patent literature 1), insulating substrates with electrodes attached thereto, heat dissipation plates, and heatsinks are provided above and below a power semiconductor device so as to cool the power semiconductor device from above and below.

Japanese Laid Open Patent Publication No. 2007-281163 (Patent literature 2) discloses the structure in which a refrigerant jets and impinges against the heat dissipation plate below the power semiconductor device so as to increase cooling performance.

However, even higher cooling performance is demanded so as to allow the power semiconductor device to be high powered and small sized.

refrigerant

### SUMMARY OF THE INVENTION

A power semiconductor module according to a first aspect of the present invention, comprises: a power semiconductor device; a first heat dissipation plate provided at one side of the power semiconductor device; a second heat dissipation plate provided at another side of the power semiconductor device; a first channel through which a refrigerant flows so as to meet the first heat dissipation plate; a second channel through which a refrigerant flows so as to meet the second heat dissipation plate; a first channel wall arranged substantially parallel to the first heat dissipation plate so as to divide the first channel; a second channel wall arranged substantially parallel to the second heat dissipation plate so as to divide the second channel; a first refrigerant outlet provided on the first channel wall in a position corresponding to the power semiconductor device; a second refrigerant outlet provided on the second channel wall in a position corresponding to the power semiconductor device; first pin fins provided on at least one of the first heat dissipation plate and the second heat dissipation plate so as to be arranged radially around at least one of the first refrigerant outlet and the second refrigerant outlet; and second pin fins arranged in a staggered manner or in a tessellated manner around the first pin fins that are arranged radially.

According a second aspect of the present invention, in the power semiconductor module according to the first aspect, it is preferable that the power semiconductor device comprises a plurality of power semiconductor chips with high heating value, and a power semiconductor chip with low heating value; a plurality of the first refrigerant outlets are provided on the first channel wall in the position corresponding to the power semiconductor chips with high heating value; a plurality of the second refrigerant outlets are provided on the second channel wall in the position corresponding to the power semiconductor chips with high heating value; the first pin fins are provided on at least one of the first heat dissipation plate and the second heat dissipation plate so as to be arranged radially around at least either the first refrigerant outlets or the second refrigerant outlets; and the second pin fins are arranged in a staggered manner around the first pin fins.

A power semiconductor module according to a third aspect of the present invention comprises: a power semiconductor device; a first heat dissipation plate provided at one side of the power semiconductor device; a second heat dissipation plate provided at another side of the power semiconductor device; a first channel through which a refrigerant flows so as to meet the first heat dissipation plate; a second channel through which a refrigerant flows so as to meet the second heat dissipation plate; a first channel wall arranged substantially parallel to the first heat dissipation plate so as to divide the first channel; a second channel wall arranged substantially parallel to the second heat dissipation plate so as to divide the second channel; a first refrigerant outlet provided on the first channel wall in a position corresponding to the power semiconductor device; a second refrigerant outlet provided on the second channel wall in a position corresponding to the power semiconductor device; first holes provided on at least one of the first heat dissipation plate and the second heat dissipation plate so as to be arranged concentrically around at least one of the first refrigerant outlet and the second refrigerant outlet, with each hole formed in a cylindrical shape, in a conical shape or in a half-cone shape; and second holes arranged in a staggered manner around the first holes that are arranged radially, with each hole formed in a cylindrical shape, in a conical shape or in a half-cone shape.

According to a fourth aspect of the present invention, in the power semiconductor module according to the third aspect, it is preferable that the power semiconductor device comprises a plurality of power semiconductor chips with high heating value, and a power semiconductor chip with low heating value; a plurality of the first refrigerant outlets are provided on the first channel wall in the position corresponding to the power semiconductor chips with high heating value; a plurality of the second refrigerant outlets are provided on the second channel wall in the position corresponding to the power semiconductor chips with high heating value; the first holes are provided on at least one of the first heat dissipation plate and the second heat dissipation plate so as to be arranged concentrically around at least either the first refrigerant outlets or the second refrigerant outlets; and the second holes are arranged in a staggered manner around the first holes.

A power semiconductor module according to a fifth aspect of the present invention comprises: a power semiconductor device; a first heat dissipation plate provided at one side of the power semiconductor device; a second heat dissipation plate provided at another side of the power semiconductor device; a first channel through which a refrigerant flows so as to meet the first heat dissipation plate; a second channel through which a refrigerant flows so as to meet the second heat dissipation plate; a first channel wall arranged substantially parallel to the first heat dissipation plate so as to divide the first channel; a second channel wall arranged substantially parallel to the second heat dissipation plate so as to divide the second channel; a first refrigerant outlet provided on the first channel wall in a position corresponding to the power semiconductor device; a second refrigerant outlet provided on the second channel wall in a position corresponding to the power semiconductor device; first flat fins provided on at least one of the first heat dissipation plate and the second heat dissipation plate so as to be arranged radially around at least one of the first refrigerant outlet and the second refrigerant outlet; and second flat fins arranged in parallel to one another around the first flat fins that are arranged radially.

A power semiconductor module according to a sixth aspect of the present invention comprises: a power semiconductor device; a first heat dissipation plate provided at one side of the power semiconductor device; a second heat dissipation plate provided at another side of the power semiconductor device; a first channel through which a refrigerant flows so as to meet the first heat dissipation plate; a second channel through which a refrigerant flows so as to meet the second heat dissipation plate; a first channel wall arranged substantially parallel to the first heat dissipation plate so as to divide the first channel; a second channel wall arranged substantially parallel to the second heat dissipation plate so as to divide the second channel; a first refrigerant outlet provided on the first channel wall in a position corresponding to the power semiconductor device; a second refrigerant outlet provided on the second channel wall in a position corresponding to the power semiconductor device; first grooves formed on at least one of the first heat dissipation plate and the second heat dissipation plate so as to be arranged radially around at least one of the first refrigerant outlet and the second refrigerant outlet; and second grooves arranged in parallel to one another around the first grooves that are arranged radially.

According to a seventh aspect of the present invention, in the power semiconductor module according to the fifth or sixth aspect, it is preferable that the power semiconductor device comprises a plurality of power semiconductor chips with high heating value, and a power semiconductor chip with low heating value; a plurality of the first refrigerant outlets are provided on the first channel wall in the position corresponding to the power semiconductor chips with high heating value; a plurality of the second refrigerant outlets are provided on the second channel wall in the position corresponding to the power semiconductor chips with high heating value; the first flat fins or the first grooves are provided on at least one of the first heat dissipation plate and the second heat dissipation plate so as to be arranged radially around at least either the first refrigerant outlets or the second refrigerant outlets; and the second flat pins or the second grooves are arranged in parallel around the first flat fins or the first grooves.

According to the eighth aspect of the present invention, in the power semiconductor module according to the second aspect, the plurality of refrigerant outlets may be arranged concentrically.

According to a ninth aspect of the present invention, in the power semiconductor module according to the first through sixth aspects, a cross-sectional area of the first refrigerant outlet which is provided at a gate side of the power semiconductor device may be smaller than a cross-sectional area of the second refrigerant outlet.

According to a tenth aspect of the present invention, in the power semiconductor module according to the first aspect, a maximum part of a diameter of each of the pin fins may be equal to or less than 1 mm.

According to a eleventh aspect of the present invention, in the power semiconductor module according to the third aspect, a maximum part of a diameter of each of the holes may be equal to or less than 1 mm.

### BRIEF DESCRIPTION OF THE DRAWINGS

FIG. 1 is a cross-sectional view of a power semiconductor module in a first embodiment of the present invention.

FIG. 2 is an enlarged view of a seal part of the power semiconductor module in the first embodiment of the present invention.

FIG. 3 shows the arrangement of radiating fins of the power semiconductor module in the first embodiment of the present invention.

FIG. 4 shows the arrangement of radiating fins of a power semiconductor module in which the number of power semiconductor devices are increased in the first embodiment of the present invention.

FIG. 5 shows the arrangement of cooling fins of a power semiconductor module in which the number of power semiconductor devices are further increased in the first embodiment of the present invention.

FIG. 6 shows the arrangement of a plurality of refrigerant outlets and fins of a power semiconductor module in the first embodiment of the present invention.

FIG. 7 shows the shape and arrangement of radiating fins of a power semiconductor module in a second embodiment of the present invention.

FIG. 8 shows the arrangement of radiating fins of the power semiconductor module in which the number of power semiconductor devices is increased in the second embodiment of the present invention.

FIG. 9 is a cross-sectional view of a power semiconductor module in a third embodiment of the present invention.

FIG. 10 is a cross-sectional view of a power semiconductor module in a fourth embodiment of the present invention.

FIG. 11 is a cross-sectional view of a power semiconductor module in a fifth embodiment of the present invention.

FIGS. 12A and 12B show the arrangement of holes of the power semiconductor module in the fifth embodiment of the present invention.

### DESCRIPTION OF PREFERRED EMBODIMENTS

The following is an explanation of embodiments of the present invention, given in reference to drawings.

### First Embodiment

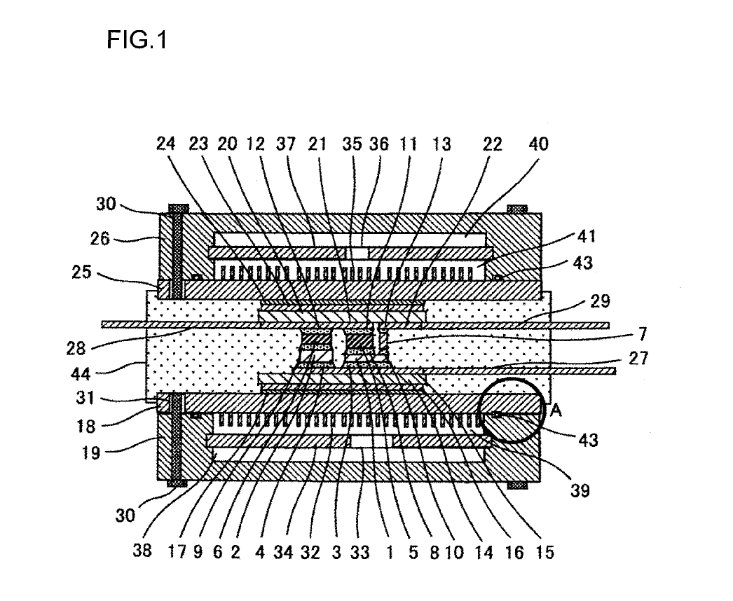

FIG. 1 is a cross-sectional view of a power semiconductor module in the first embodiment of the present invention. In FIG. 1, the power semiconductor module includes power semiconductor devices 1 and 2 such as an IGBT or a free wheel diode. The lower side of the power semiconductor devices 1 and 2 is connected to copper foil 15 that is provided to form a circuit pattern on the upper surface of a lower insulating substrate 14 by bonding means 3 and 4 such as a first soldering or the like. The upper sides of the power semiconductor devices 1 and 2 are connected to spacers 5, 6, and 7 respectively by bonding means 8, 9, and 10 such as a second soldering or the like.

For example, in the case where the power semiconductor device 1 is an IGBT device, an emitter electrode (not shown) and a gate electrode (not shown) having been provided on the upper side of the power semiconductor device are respectively connected to the spacers 5 and 7 by the bonding means 8 and 10 such as soldering or the like. In the case where the power semiconductor device 2 is a free wheel diode device, an anode electrode (not shown) having been provided on the upper side of the power semiconductor device is connected to the spacer 6 by the bonding material 9 such as soldering or the like.

The spacers 5, 6, and 7 serve to adjust the height when the thicknesses of the power semiconductor devices 1 and 2 are different from each other. Furthermore, the spacers 5, 6, and 7 prevent electrical discharge which may be caused when a distance between electrodes 27 and 28 that lie below and above the spacers, respectively, is too small.

It is preferable that the spacers are small both in electrical resistance and thermal resistance. The spacers are made from copper-carbon composite material, copper-invar jointing material, or the like, as well as copper. Since the coefficient of thermal expansion of copper-carbon composite material, copper-invar bonding material, and the like are smaller than that of copper, thermal distortion due to heat of the solderings 3 and 4 is reduced, thereby improving reliability.

The lower insulating substrate 14 is made from, for instance, aluminum nitride (AlN), alumina (Al₂O₃), silicon nitride (Si₃N₄), boron nitride (BN), or the like. The copper foils or aluminum foils 15 and 16 are applied directly or by soldering to the both sides of the lower insulating substrate 14 in advance.

The upper sides of the spacers 5, 6, and 7 are connected to copper foils 21 and 22 that are provided to form circuit patterns on the lower surface of an upper insulating substrate 20, respectively by bonding means 11, 12, and 13 such as a third soldering or the like.

For example, in the case where an IGBT device is used, the copper foil 15 and a collector electrode (not shown) of the power semiconductor device 1 are electrically connected to each other via the soldering 3, and a lead electrode 27 protrudes from the copper foil 15. The copper foil 16, which is provided on the lower surface of the lower insulating substrate 14, and a lower heat dissipation plate 18 are connected to each other by a bonding means 17 such as a fourth soldering or the like. The heat dissipation plate 18 is made from copper, copper-molybdenum, AlSiC, or the like.

Fins 32 are directly provided on the lower part of the heat dissipation plate 18. The fins 32 are fixed by welding, brazing, or the like to the heat dissipation plate 18, or integrally formed with the heat dissipation plate 18. A case 19 is provided on the lower side of the heat dissipation plate 18. Inside the case 19 is provided with a cooling channel that is divided into a lower cooling channel 38 and an upper cooling channel 39 by a divider (channel wall) 34.

On a part of the divider 34 directly below the power semiconductor device 1, a refrigerant outlet 33 is formed. A refrigerant such as antifreeze liquid in the lower cooling channel 38, passes through the refrigerant outlet 33, and impinges against the heat dissipation plate 18. This type of structure is referred to as a jet cooling structure.

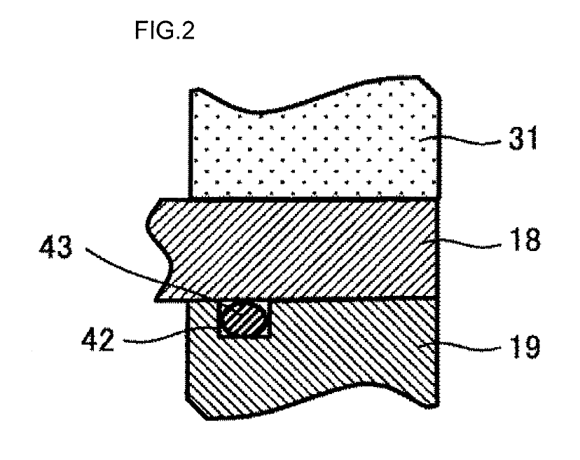

As FIG. 2 shows, the case 19 is provided with a groove 42 for an O-ring, and the gap between the heat dissipation plate 18 and the case 19 is sealed with an O-ring 43. The heat dissipation plate 18 and the case 19 are connected to each other using a bolt 30 and a female screw 31 that is provided on a base to be fitted with the bolt. The female screw 31 may be formed with a helical coil wire screw thread insert.

The upper insulating substrate 20 is made from the same material as that is used for the lower insulating substrate 14. Copper foils or aluminum foils 21 and 22 are applied directly or by soldering to the lower side of the lower insulating substrate 14 while copper foil or aluminum foil 23 is applied directly or soldering to the upper side of the lower insulating substrate 14. The upper sides of the spacers 5, 6, and 7 are connected to the copper foils 21, and 22 respectively by bonding means 11, 12, and 13 such as the third soldering or the like. Lead electrodes 28 and 29 protrude outward from the copper foils 21 and 22 respectively.

The copper foil 23 applied on the upper side of the upper insulating substrate 20 is connected to an upper heat dissipation plate 25 by a bonding means 24 such as a fifth soldering or the like. The upper heat dissipation plate 25 is made from copper, copper-molybdenum, AlSiC, or the like.

Fins 35 are directly provided on the upper part of the upper heat dissipation plate 25. The fins 35 are fixed by welding, brazing, or the like, or integrally formed with the heat dissipation plate 25. A case 26 is provided on the upper side of the heat dissipation plate 25. Inside the case 26 is provided with a cooling channel that is divided into an upper cooling channel 40 and a lower cooling channel 41 by a divider 37.

On a part of the divider 37 directly above the power semiconductor device 1, a refrigerant outlet 36 is formed. A refrigerant in the upper cooling channel 40, passes through the refrigerant outlet 36, and impinges against the heat dissipation plate 25. The gap between the heat dissipation plate 25 and the case 26 is sealed with the O-ring 43.

The whole or parts of surfaces or sides of the power semiconductor devices 1, 2, the insulating substrates 14, 20, and the copper foils 15, 16, 21, 22, 23, the electrodes 27, 28, and 29 having been connected to the insulating substrates are thinly coated with a flexible resin such as polyimide based or polyamide-imide based, and sealed with an epoxy based resin 44 after curing.

It is preferable to use a lead-free bonding material for all the bonding materials in consideration of environmental issues. A high-temperature bonding material in which, for example, copper particles and tin particles are mixed is used for the first bonding materials 3 and 4 that connect the power semiconductor devices 1 and 2 with the copper foil 15, the second bonding materials 8, 9, and 10 that connect the power semiconductor devices 1 and 2 with the spacer 5, 6, and 7, and the third bonding material that connects the spacer 5, 6, and 7 with the copper foils 21 and 22.

A bonding material having a lower melting point than that of the first, second, or third bonding materials, e.g., Sn-3Ag-0.5Cu lead-free soldering, is used for the fourth bonding material 17 that connects the lower insulating substrate 14 with the lower heat dissipation plate 18, and the fifth bonding material 24 that connects the upper insulating substrate 20 with the upper heat dissipation plate 25.

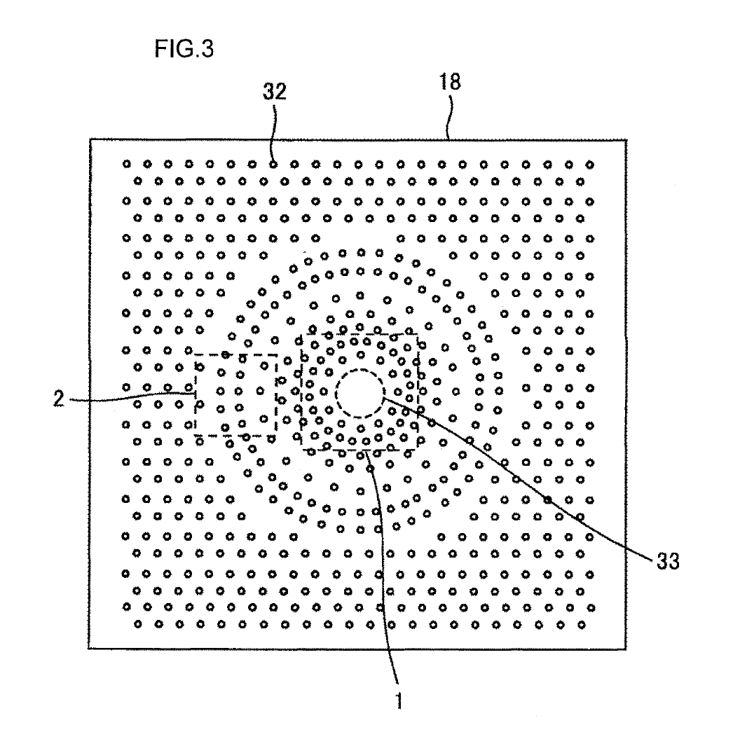

The arrangement of the fins 32 provided on the lower heat dissipation plate 18 is now shown with reference to FIG. 3. In the arrangement of FIG. 3, pin fins are used as the fins 32. A heating value of the power semiconductor device 1 (may be referred to as a chip 1) is higher than a heating value of the power semiconductor device 2 (may be refereed to as a chip 2). As shown in FIG. 3, the refrigerant outlet 33 is formed on the divider 34 so as to position directly below the chip 1 a loss of which is higher than a loss of a the chip 2. On the lower heat dissipation plate 18, the pin fins 32 are arranged radially around a position corresponding to the refrigerant outlet 33. The pin fins 32 in peripheral areas away from the chip 1 are arranged in a staggered manner, or may be arranged in a grid manner. Since the flow of the refrigerant changes near the boundary between the radially-arranged area and its surrounding area, fin spacing is widely arranged so as to ensure a smooth flow and to reduce pressure loss. Exits for refrigerant are provided in the case 19 at positions corresponding to the upper and lower ends of the heat dissipation plate 18 in FIG. 3. Radial arrangement of the fins 32 near the jet part corresponding to the outlet 33 and staggered arrangement of the peripheral fins 32s enable to reduce path loss between the jet part and the exits of the refrigerant.

When the fins 32 are pin fins with the diameter of the maximum part being equal to or less than 1 mm and the height being about 1 mm˜5 mm, high cooling efficiency is achieved. The arrangement of the fins 35 provided on the upper heat dissipation plate 25 is similar to above. The refrigerant outlet 36 is positioned on a vertical axis extending from the center of the spacer 5 and is formed as a circular opening around the vertical axis. The fins 35 are arranged radially around the circular outlet 36. This arrangement is employed, taking into consideration that the main heat dissipation path from the upper side of the chip 1 passes through the spacer 5.

In FIG. 1, the area of the refrigerant outlet 36 at the gate side is set smaller than the area of the refrigerant outlet 33 at the other side. By this configuration, since the refrigerant impinges against a portion corresponding to the chip with a higher heating value in a concentrated manner, the cooling efficiency is improved.

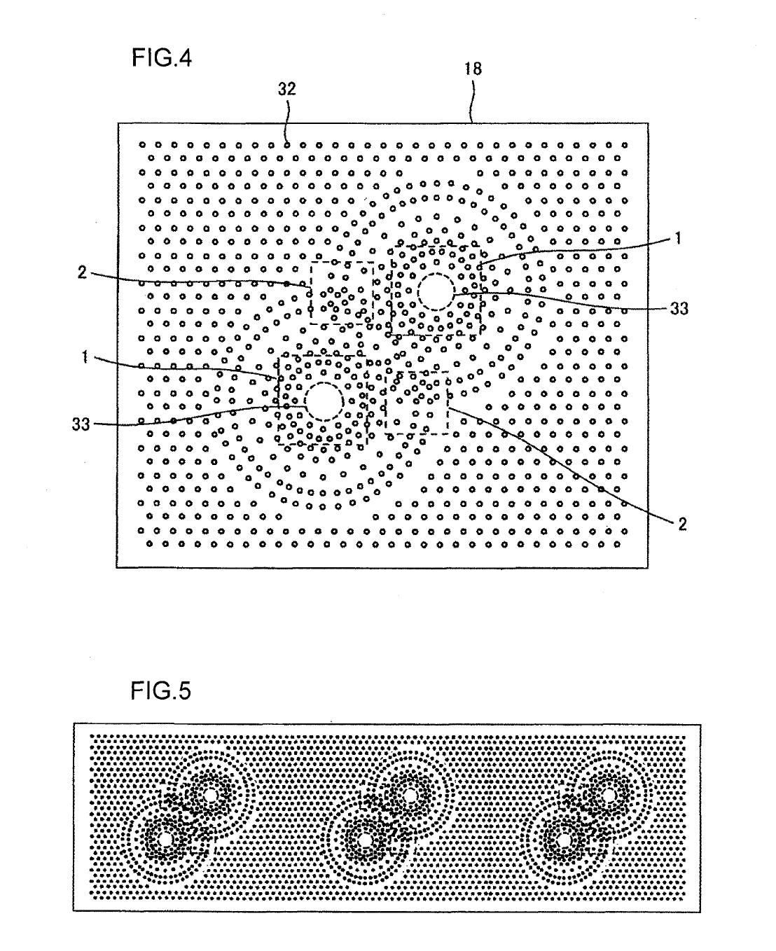

FIG. 4 shows the arrangement of fins 32 in the case where two chips 1 with high heating value and high loss and two chips 2 with lower heating value and low loss are provided in the module. Two refrigerant outlets 33 are formed on the divider 34 directly below the two e chips 1 with high loss, respectively. On the lower heat dissipation plate 18, pin fins 32 are arranged radially around positions each corresponding to one of the refrigerant outlets 33. In the area where two concentric circles interfere, the number of pin fins 32 are properly reduced so as to prevent pressure loss from increasing.

FIG. 5 shows the arrangement of fins 32 in the case where threes sets of the chip 1 and the chip 2 are provided in the module. Basically, in FIG. 5, the arrangements of the fins 32 shown in FIG. 4 are juxtaposed. In this case, it is preferable to provide a plurality of exits for the refrigerant in the case 19 at positions corresponding to the upper and lower ends of the heat dissipation plate 18 in FIG. 5.

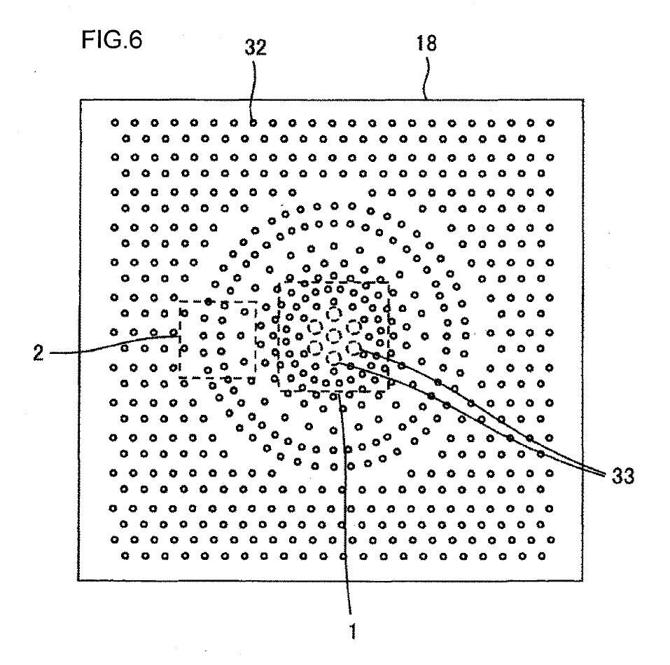

FIG. 6 presents an example in which a plurality of the refrigerant outlets 33 are formed in the divider 34 so as to be positioned directly below the chip 1. A plurality of outlets 36 may be provided above the chip 1 on the divider 37 in a similar manner. As shown in FIG. 6, the refrigerant outlets 33 are radially arranged. Arranging the plurality of refrigerant outlets increases the flow rate of the refrigerant and improves the heat transfer coefficient.

According to the structure of the first embodiment, the fine pin fins 32 and 35 are arranged in combination of a radial manner and a staggered manner so as to jet-cool the power semiconductor device 1 from above and below, so that high cooling performance can be achieved with small pressure loss. In this manner, the power semiconductor device and consequently the entire power semiconductor module are achieved to be downsized.

Expressions such as “above” and “below” are used in the above explanations for the sake of convenience. However, the arrangement may be horizontal or in another direction, wherein the expressions, above and below, may be replaced by the expressions, right and left or the like, for example in the horizontal case.

### Second Embodiment

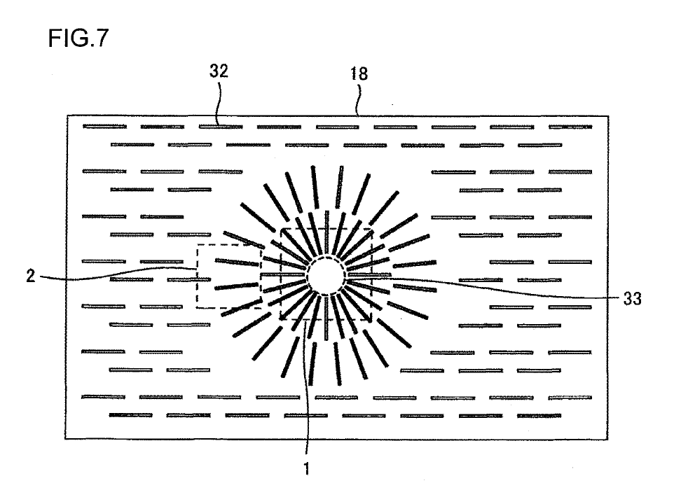

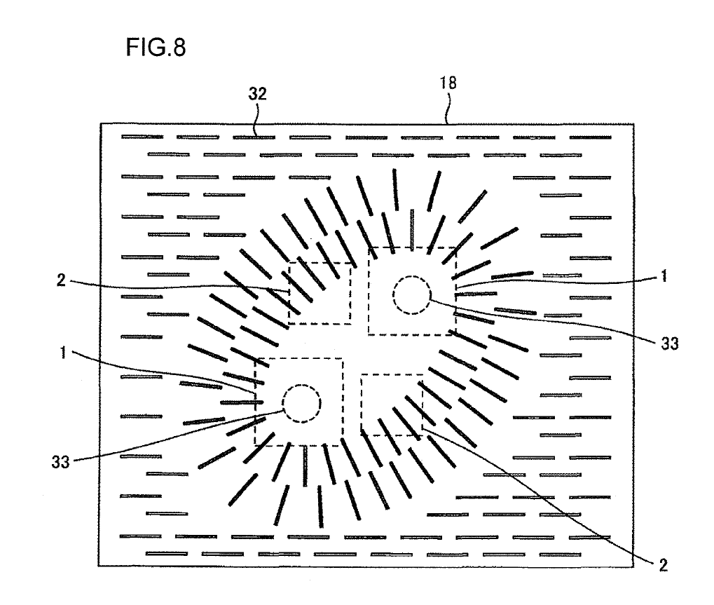

FIGS. 7 and 8 present the shapes and arrangements of fins 32 of the lower heat dissipation plate 18 in the second embodiment of the present invention. In the second embodiment, flat fins are used as the fins 32. In FIG. 7, the flat fins 32 are arranged on the heat dissipation plate 18 radially around a position corresponding to the refrigerant outlet 33. In other words, the surface of each fin 32 is set along the radial direction as shown in FIG. 7. On the periphery away from the position corresponding to the refrigerant outlet 33, the flat fins 32 are arranged in parallel to each other. Radial arrangement of the flat fins 32 near the outlet 33, which is a jet part, and parallel arrangement of the peripheral fins enable to reduce path loss between the jet part and the exits of the refrigerant. It is preferable for the flat fins 32 to be equal to or less than 1 mm thin in the maximum part, about 2 mm to 5 mm long along the heat dissipation plate 18, and about 1 mm˜5 mm high in the vertical direction with respect to the heat dissipation plate 18.

FIG. 8 presents the arrangement of flat fins 32 in the case where two chips 1 with high heating value and high loss and two chips 2 with lower heating value and low loss are provided in the module. As shown in FIG. 8, the flat fins 32 are arranged radially around a generally oval area that includes two of the refrigerant outlets 33. On the periphery away from the refrigerant outlets 33, the flat fins 32 are arranged in parallel to each other. Exits for the refrigerant are provided in the case 19 at positions corresponding to the right and left ends of the heat dissipation plate 18 in FIGS. 7 and 8.

The fins 35 on the upper heat dissipation plate 25 may as well be formed as flat fins and arranged in the similar manner as shown in FIGS. 7 and 8.

In FIGS. 7 and 8, suitably-formed grooves in place of fins may be arranged in a similar manner on the heat dissipation plate 18. The grooves can also improve heat transfer coefficient or improve cooling performance due to an increase of heat transfer area.

According to the second embodiment, fine fat fins 32 and 35 are arranged in combination of a radial manner and a parallel manner so as to jet-cool the power device from above and below, so that high cooling performance can be achieved with small pressure loss. In this manner, the power semiconductor device and consequently the entire power semiconductor module are achieved to be downsized.

### Third Embodiment

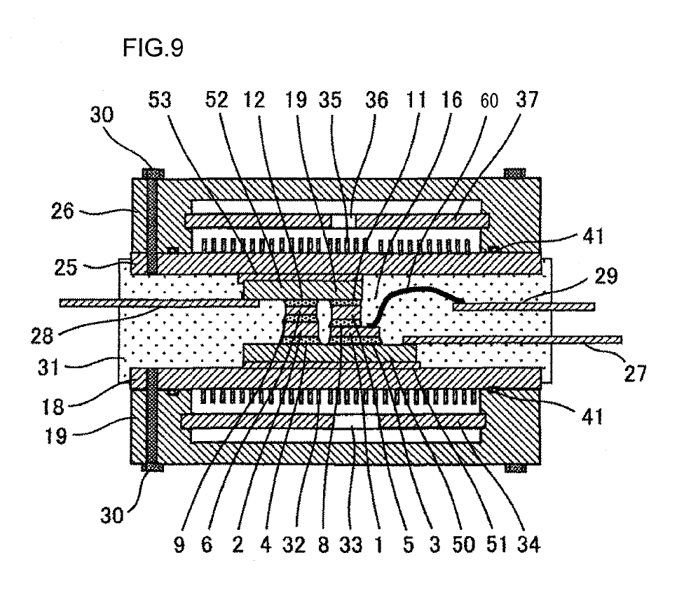

FIG. 9 presents a cross-sectional structure of the power semiconductor module in the third embodiment of the present invention.

In the third embodiment, insulation is ensured by insulation resin materials 51 and 53 in place of the insulating substrates 14 and 20 in the first embodiment of FIG. 1. An electrode 50 is provided on the insulation resin 51. The electrode 50 and the power devices 1 and 2 are connected to each other by the bonding materials 3 and 4 such as soldering. The electrode 50 is extended outward by means of the lead electrode 27. An electrode 52 is provided under the insulation resin 53. The electrode 52 and the spacer 5 and 6 are connected to each other by the bonding materials 11 and 12 such as soldering. For example, a gate electrode of an IGBT 1 is connected to an aluminium wire 60 and the electrode 29 so as to protrude outwardly. The electrode 50, the insulation resin 51, and the heat dissipation plate 18 are connected to each other in a method such as thermo-compression bonding. So are the electrode 52, the insulation resin 53, and the heat dissipation plate 25. Structures of other parts such as the shapes and arrangements of fins 32 and 35 are same as those of the first embodiment.

According to the third embodiment, the power device 1 is jet-cooled from above and below, so that high cooling performance can be achieved with small pressure loss. In this manner, the power semiconductor device and consequently the entire power semiconductor module are achieved to be downsized.

### Fourth Embodiment

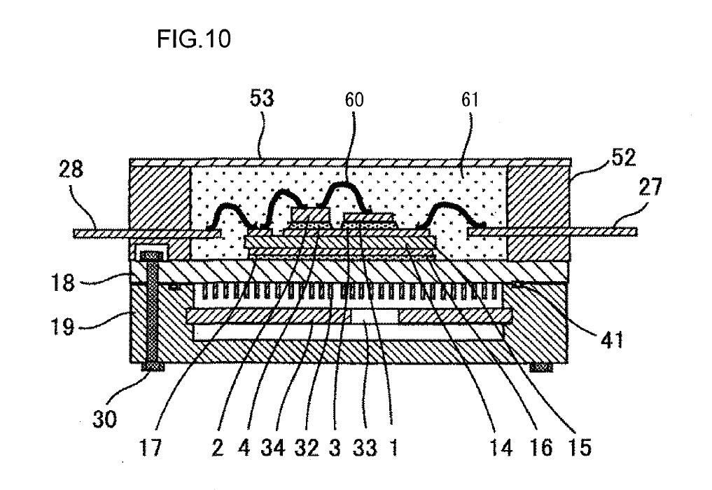

FIG. 10 presents a cross-sectional structure of the power module in the fourth embodiment of the present invention. The fourth embodiment according to FIG. 10 shows an example of one-sided cooling. The aluminum wires 60 are used for wiring on the chips 1 and 2. A silicone gel or like is used for a sealing material 61. The shapes and arrangements of fins 32 or the like are same as those of the first embodiment. Even one-sided cooling as in the fourth embodiment can achieve cooling performance higher than conventional ones by applying jet cooling and the fins arrangements as shown in FIG. 3 through FIG. 8. This enables the power semiconductor device and consequently the entire power semiconductor module to be downsized.

### Fifth Embodiment

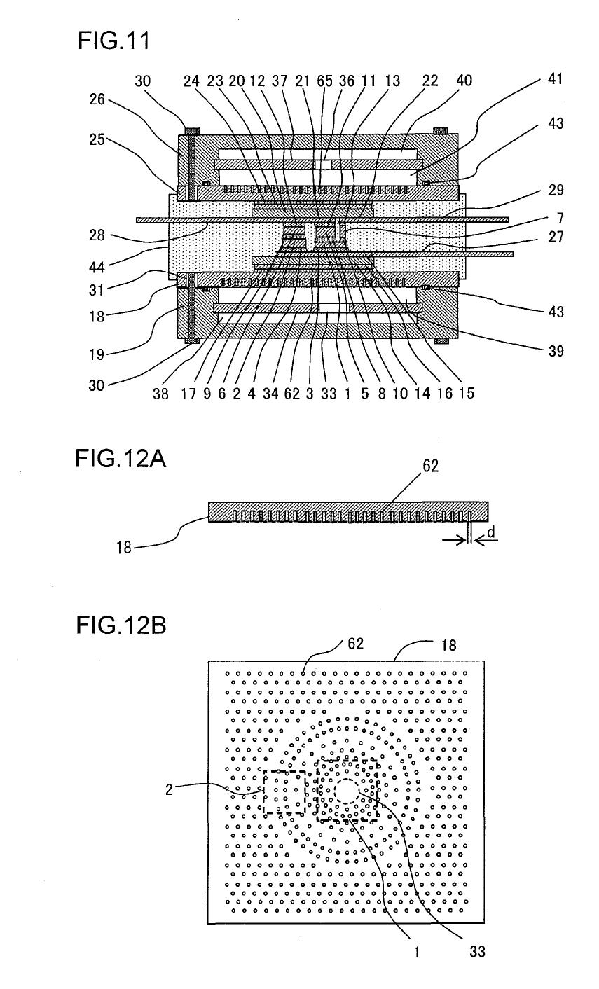

FIG. 11 shows a cross-sectional view of a power semiconductor module in the fifth embodiment of the present invention. In the fifth embodiment, circular or cylindrical holes 62 and 65 are formed in the heat dissipation plates 18 and 25. The refrigerant jets through the refrigerant outlets 33 and 36 and impinges against these holes 62 and 65, causing the flow at the surface of the heat dissipation plates 18 and 25 to be disturbed. As a result, the high heat dissipation effects can be achieved.

FIGS. 12A and 12B show the structure of the heat dissipation plate 18 and the holes 62. FIG. 12A shows a cross section of the heat dissipation plate 18 and FIG. 12B shows the arrangement of the holes 62 on the heat dissipation plate 18. By setting the diameter of the hole 62 at a maximum part to be equal to or smaller than 1 mm, a high heat transfer coefficient can be achieved at the collision part so as to improve the heat dissipation efficiency. The hole 62 may be formed in a conical shape or in a half-cone shape, in stead of the circular shape. which are cut into the heat dissipation plate

The configuration of the holes 62 shown in FIGS. 12A and 12B may be combined with the arrangement of a plurality of the refrigerant outlets 33 shown in FIG. 6. When the grooves are formed in the arrangement as shown in FIGS. 7 and 8, the arrangement of a plurality of the refrigerant outlets 33 can also be employed.

According to the power semiconductor module of the embodiments described above, the power semiconductor is cooled from both sides and heat transfer coefficient between the refrigerant and the heat dissipation plates is improved, therefore high cooling performance can be achieved.

The above-described embodiments may be adopted in a variety of power semiconductor modules, in particular, power semiconductor modules in a field that requires power increase such as vehicles.

What is claimed is:

1. A power semiconductor module, comprising:
a power semiconductor device;
a first heat dissipation plate provided at one side of the power semiconductor device;
a second heat dissipation plate provided at another side of the power semiconductor device;
a first channel through which a refrigerant flows so as to meet the first heat dissipation plate;
a second channel through which a refrigerant flows so as to meet the second heat dissipation plate;
a first channel wall arranged substantially parallel to the first heat dissipation plate so as to divide the first channel;
a second channel wall arranged substantially parallel to the second heat dissipation plate so as to divide the second channel;
a first refrigerant outlet provided on the first channel wall in a position corresponding to the power semiconductor device;
a second refrigerant outlet provided on the second channel wall in a position corresponding to the power semiconductor device;
first pin fins provided on at least one of the first heat dissipation plate and the second heat dissipation plate so as to be arranged radially around at least one of the first refrigerant outlet and the second refrigerant outlet; and
second pin fins arranged in a staggered manner or in a tessellated manner around the first pin fins that are arranged radially.

2. A power semiconductor module according to claim 1, wherein:
the power semiconductor device comprises a plurality of power semiconductor chips with high heating value, and a power semiconductor chip with low heating value;
a plurality of the first refrigerant outlets are provided on the first channel wall in the position corresponding to the power semiconductor chips with high heating value;
a plurality of the second refrigerant outlets are provided on the second channel wall in the position corresponding to the power semiconductor chips with high heating value;
the first pin fins are provided on at least one of the first heat dissipation plate and the second heat dissipation plate so as to be arranged radially around at least either the first refrigerant outlets or the second refrigerant outlets; and
the second pin fins are arranged in a staggered manner around the first pin fins.

3. A power semiconductor module, comprising:
a power semiconductor device;
a first heat dissipation plate provided at one side of the power semiconductor device;
a second heat dissipation plate provided at another side of the power semiconductor device;
a first channel through which a refrigerant flows so as to meet the first heat dissipation plate;
a second channel through which a refrigerant flows so as to meet the second heat dissipation plate;
a first channel wall arranged substantially parallel to the first heat dissipation plate so as to divide the first channel;
a second channel wall arranged substantially parallel to the second heat dissipation plate so as to divide the second channel;
a first refrigerant outlet provided on the first channel wail in a position corresponding to the power semiconductor device;
a second refrigerant outlet provided on the second channel wall in a position corresponding to the power semiconductor device;
first holes provided on at least one of the first heat dissipation plate and the second heat dissipation plate so as to be arranged concentrically around at least one of the first refrigerant outlet and the second refrigerant outlet, with each hole formed in a cylindrical shape, in a conical shape or in a half-cone shape; and
second holes arranged in a staggered manner around the first holes that are arranged radially, with each hole formed in a cylindrical shape, in a conical shape or in a half-cone shape.

4. A power semiconductor module according to claim 3, wherein:
the power semiconductor device comprises a plurality of power semiconductor chips with high heating value, and a power semiconductor chip with low heating value;
a plurality of the first refrigerant outlets are provided on the first channel wall in the position corresponding to the power semiconductor chips with high heating value;
a plurality of the second refrigerant outlets are provided on the second channel wall in the position corresponding to the power semiconductor chips with high heating value;
the first holes are provided on at least one of the first heat dissipation plate and the second heat dissipation plate so as to be arranged concentrically around at least either the first refrigerant outlets or the second refrigerant outlets; and
the second holes are arranged in a staggered manner around the first holes.

5. A power semiconductor module, comprising:
a power semiconductor device;
a first heat dissipation plate provided at one side of the power semiconductor device;
a second heat dissipation plate provided at another side of the power semiconductor device;
a first channel through which a refrigerant flows so as to meet the first heat dissipation plate;
a second channel through which a refrigerant flows so as to meet the second heat dissipation plate;
a first channel wall arranged substantially parallel to the first heat dissipation plate so as to divide the first channel;
a second channel wall arranged substantially parallel to the second heat dissipation plate so as to divide the second channel;
a first refrigerant outlet provided on the first channel wall in a position corresponding to the power semiconductor device;
a second refrigerant outlet provided on the second channel wall in a position corresponding to the power semiconductor device;
first flat fins provided on at least one of the first heat dissipation plate and the second heat dissipation plate so as to be arranged radially around at least one of the first refrigerant outlet and the second refrigerant outlet; and
second flat fins arranged in parallel to one another around the first flat fins that are arranged radially.

6. A power semiconductor module, comprising:
a power semiconductor device;
a first heat dissipation plate provided at one side of the power semiconductor device;
a second heat dissipation plate provided at another side of the power semiconductor device;
a first channel through which a refrigerant flows so as to meet the first heat dissipation plate;
a second channel through which a refrigerant flows so as to meet the second heat dissipation plate;
a first channel wall arranged substantially parallel to the first heat dissipation plate so as to divide the first channel;
a second channel wall arranged substantially parallel to the second heat dissipation plate so as to divide the second channel;
a first refrigerant outlet provided on the first channel wall in a position corresponding to the power semiconductor device;
a second refrigerant outlet provided on the second channel wall in a position corresponding to the power semiconductor device;
first grooves formed on at least one of the first heat dissipation plate and the second heat dissipation plate so as to be arranged radially around at least one of the first refrigerant outlet and the second refrigerant outlet; and
second grooves arranged in parallel to one another around the first grooves that are arranged radially.

7. A power semiconductor module according to claim 5, wherein:
the power semiconductor device comprises a plurality of power semiconductor chips with high heating value, and a power semiconductor chip with low heating value;
a plurality of the first refrigerant outlets are provided on the first channel wall in the position corresponding to the power semiconductor chips with high heating value;
a plurality of the second refrigerant outlets are provided on the second channel wall in the position corresponding to the power semiconductor chips with high heating value;
the first flat fins are provided on at least one of the first heat dissipation plate and the second heat dissipation plate so as to be arranged radially around at least either the first refrigerant outlets or the second refrigerant outlets; and
the second flat pins are arranged in parallel around the first flat fins.

8. A power semiconductor module according to claim 2, wherein:
the plurality of refrigerant outlets are arranged concentrically.

9. A power semiconductor module according to claim 1, wherein:
a cross-sectional area of the first refrigerant outlet which is provided at a gate side of the power semiconductor device is smaller than a cross-sectional area of the second refrigerant outlet.

10. A power semiconductor module according to claim 1, wherein:
a maximum part of a diameter of each of the pin fins is equal to or less than 1 mm.

11. A power semiconductor module according to claim 3, wherein:
a maximum part of a diameter of each of the holes is equal to or less than 1 mm.
